(19) United States
(12) Patent Application Publication
(10) Pub. No.: US 2008/0198044 A1
(43) Pub. Date: Aug. 21, 2008

(54) COMPUTER AND METHOD FOR PROCESSING KEYBOARD INPUT THEREOF

(75) Inventors: Ding Long Liu, Taipei (TW); Jen-Chung Yang, Taipei (TW); Sheng Yi Chen, Taipei (TW); Yao-Ming Yang, Taipei (TW)

Correspondence Address: QUINTERO LAW OFFICE, PC, 2210 MAIN STREET, SUITE 200, SANTA MONICA, CA, 90405, US

(73) Assignee: ASUSTEK COMPUTER INC., TAIPEI CITY (TW)

(21) Appl. No.: 12/024,917

(22) Filed: Feb. 1, 2008

(30) Foreign Application Priority Data
Feb. 15, 2007 (TW) TW96105675

(51) Int. Cl. H03K 17/94

(52) U.S. Cl. 341/26

(57) ABSTRACT

A computer and a method for processing keyboard input thereof is disclosed. The method includes the steps of receiving an interrupt request; reading a scan code stored in a scan code buffer; determining whether the scan code is a predetermined scan code representing an Fn key; reading an event code stored in an event code buffer if the scan code is the predetermined scan code; and executing a corresponding service program or function according to the event code.

### BACKGROUND OF THE INVENTION

1. Field of the Invention

The invention relates to a keyboard input technology and, more particularly, to a computer and a method for processing keyboard input thereof.

2. Description of the Related Art

In many computer systems (such as desktop system), a keyboard as a main input device is used to input commands or data into a computer system. In such computer, the keyboard is coupled to a processing unit via a keyboard interface (such as a keyboard controller). Generally speaking, a computer keyboard uses a grid-type or matrix-type switch assembly. When a key on a specific cross-section of the grid or matrix switch assembly is pressed down, the keyboard controller built in the keyboard or provided on the motherboard of the computer determines the pressed key according to the position of the grid.

However, since the size of a portable computer (such as a notebook or an ultra mobile portable computer (UMPC)) is reduced, and the computer usually has many additional functions such as switching the displayed frame on a screen of a computer or a projector, adjusting the volume, or adjusting the brightness of the frame, and the number of the keys on the keyboard assembled in the computer usually cannot support these functions individually. Hence, an Fn key (F Lock key) that works like a shift key to activate the second function on a dual-purpose key, typically found on laptops to reduce keyboard size. It is different than the function keys F1, F2, etc.

For example, the “Backspace” key is originally a cancel key for cancelling inputted letters or numbers. However, if the Fn key and the “backspace” key are pressed simultaneously, the loudspeaker of the computer may be in a mute status. In other words, parts of the keys on the keyboard have two functions. When the key is pressed down individually, a common function such as letter inputting, cancelling or renewing is executed. When the key is used with the Fn key, a specific function is executed.

In addition, in such portable computer, the Fn key usually cooperates with the function keys (such as F1˜F12) on the keyboard to execute functions such as opening the keyboard locking, executing the network connecting application, outputting images to a projector, executing the pausing function of the audio and video program, executing the fast forwarding function of the audio and video program, executing the reversing function of the audio and video program, executing the sleeping mode, adjusting the brightness of the display screen, turning up the volume of the loudspeaker, turning down the volume of the loudspeaker, executing the mute function, and so on. Therefore, extra functions that the keys can control may be added without increasing the size of the keyboard.

### BRIEF SUMMARY OF THE INVENTION

The invention provides a method for processing keyboard input. The method includes the steps of receiving an interrupt request; reading a scan code stored in a scan code buffer; determining whether the scan code is a predetermined scan code; if the scan code is a predetermined scan code, reading an event code stored in an event code buffer and executing a corresponding service program or function according to the event code.

The invention also provides a computer including a keyboard which has a plurality of alphanumeric keys, a plurality of function keys and an Fn key, a processing unit, a keyboard controller coupled to the keyboard so that the keyboard controller generates an interrupt signal to make the processing unit execute a corresponding service program or function when one of the alphanumeric keys, one of the function keys, the Fn key or the key combination thereof is pressed.

The invention also provides a computer including a keyboard which has a plurality of alphanumeric keys, a plurality of function keys and an Fn key, a keyboard controller which is coupled to the keyboard and includes a scan code buffer and an event code buffer, and a processing unit. After receiving an interrupt request, the processing unit reads a scan code stored in the scan code buffer, determines whether the scan code represents a predetermined scan code of the function hotkey, reads an event code stored in an event code buffer and execute a corresponding service program or function according to the event code if the scan code is a predetermined scan code.

These and other features, aspects, and advantages of the present invention will become better understood with regard to the following description, appended claims, and accompanying drawings.

### BRIEF DESCRIPTION OF THE DRAWINGS

FIG. 1 is a function block diagram of a computer of one embodiment of the invention.

FIG. 2 is a schematic diagram showing a keyboard.

FIG. 3 is a step flowchart of the keyboard input method of one embodiment of the invention.

### DETAILED DESCRIPTION OF THE EMBODIMENTS

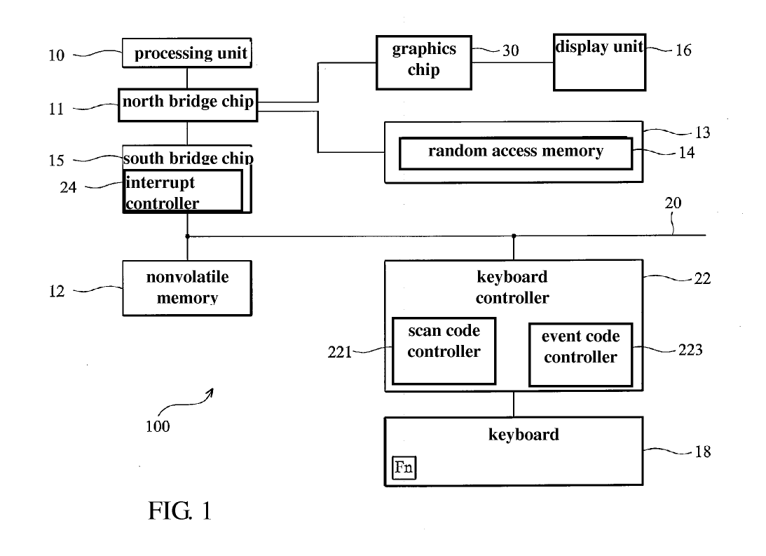

FIG. 1 is a function block diagram of a computer of one embodiment of the invention. The computer 100 includes a processing unit 10, a north bridge chip 11, a nonvolatile memory 12, a memory unit 13, a south bridge chip 15, a graphics chip 30, a display unit 16, a keyboard 18, a bus 20 and a keyboard controller 22. The memory unit 13 includes a random access memory (RAM) 14. The south bridge chip 15 includes an interrupt controller 24. The keyboard controller 22 includes a scan code buffer 221 and an event code buffer 223.

In the embodiment, the computer 100 may be a desktop, a server or a portable computer, wherein the portable computer may be the notebook, the tablet portable computer (tablet PC), the palmtop or the ultra mobile personal computer (UMPC). In this embodiment, the nonvolatile memory 12 is a flash memory. In other embodiments, the nonvolatile memory 12 may be a read only memory (ROM). In this embodiment, the display unit 16 is a liquid crystal display (LCD) panel. In other embodiments, the display unit 16 may be a plasma display panel, an organic light emitting display panel, field emitting display panel or a cathode ray tubes display panel.

The processing unit 10 is coupled to the north bridge chip 11, and the processing unit 10 may be a microprocessor or a central processing unit (CPU). The north bridge chip 11 is coupled to the processing unit 10, the south bridge chip 15, the graphics chip 30 and the memory unit 13, respectively. The graphics chip 30 is coupled to the display unit 16. In other embodiment, the graphics chip 30 may be replaced by a display card.

The south bridge chip 15 is coupled to the north bridge chip 11, the nonvolatile memory 12 and the keyboard controller 22, respectively. In other embodiments, the south bridge chip 15 may be coupled to other peripheral devices of the computer such as a disk drive, an optical disc drive or a printer. In this way, the processing unit 10 can access the data stored in the memory unit 13 via the north bridge chip 11, and the processing unit 10 also can do relative operations of the nonvolatile memory 12 and the keyboard controller 22 via the south bridge chip 15.

In this embodiment, the south bridge chip 15 is coupled to nonvolatile memory 12 via industry standard architecture (ISA) bus. In this embodiment, the bus 20 between the keyboard controller 22 and south bridge chip 15 is low pin count (LPC) bus. In other embodiment, the bus 20 between the keyboard controller 22 and the south bridge chip 15 may be ISA bus or SPI bus.

The south bridge chip 15 is coupled between the north bridge chip 11 and the bus 20 to control the relationship between the processing unit 10 and the keyboard controller 22 connected to the bus 20. In addition, the interrupt controller 24 in the south bridge chip 15 can receive the interrupt signal such as IRQ1 of the keyboard controller 22 via bus 20 to generate a corresponding interrupt request to inform the processing unit 10 to communicate with the keyboard controller 22 to do relative operation. Similarly, the south bridge chip 15 also can receive interrupt signals (such as IRQ0 and IRQ2˜IRQ15) of other computer peripheral device via other buses (such as peripheral component interconnect (PCI) bus, universal serial bus (USB), serial advanced technology attachment (SATA) bus or intelligent drive electronics (IDE) bus) to generate corresponding interrupt requests to inform the processing unit 10 to communicate with the other peripheral devices to do relative operation.

The keyboard controller 22 is disposed on the motherboard. Each key on the keyboard 18 has a corresponding communicate switch coupled to the keyboard controller 22 via a connecting wire. In this way, the keyboard controller 22 can scan the communicate switches at predetermined period (such as several milliseconds) to determine whether one or several keys are pressed to make the corresponding communicate switches generate a keyboard signal, so that the keyboard controller 22 can generate a corresponding scan code according to the keyboard signal of different keys. The keyboard controller 22 stores the scan code into the scan code buffer 221 and generates an interrupt signal IRQ1 and outputs the interrupt signal IRQ1 to the interrupt controller 24 of the south bridge chip 15. When some specific keys on the keyboard 18 are pressed, the keyboard controller 22 generates a corresponding event code and stores the corresponding event code into the event code buffer 223.

The interrupt controller 24 receives the interrupt signals such as IRQ0˜IRQ15 of each computer peripheral device via several interrupt request signal lines to generate corresponding interrupt requests to inform the processing unit 10 that other modules want to communicate.

In the embodiment, the keyboard controller 22 and the interrupt controller 24 transmit interrupt signals (such as IRQ1) only via an interrupt request signal line. That is, in the embodiment, no matter one key is pressed or several keys are pressed on the keyboard 18, the keyboard controller 22 transmits the same interrupt signal to the interrupt controller 24 via the same interrupt request signal line. The situation that several keys are pressed is, for example, the Fn key and a single function key (such as one of F1˜F12) are pressed simultaneously, the Fn key and a single letter key are pressed simultaneously, or several alphanumeric keys (such as Ctrl key+Alt key+Del key) are pressed simultaneously.

When the interrupt controller 24 receives the interrupt signal IRQ1, the interrupt controller 24 generates a keyboard interrupt request and transmits the keyboard interrupt request to the processing unit 10. Then, the processing unit 10 sends an acknowledge message to the interrupt controller 24 to inform the interrupt controller 24 that the processing unit 10 has received the keyboard interrupt request generated by it. After that, the processing unit 10 executes a keyboard interrupt service routine (KBSR) and makes the KBSR obtain the generated scan code via the keyboard controller 22 to execute relative operations such as converting the scan code to the ASCII character which represents the alphanumeric key pressed by the user or executing the function determined by the pressed character.

General speaking, the KBSR may be stored in the nonvolatile memory 12 or the RAM 14. In some embodiments, the KBSR used by the keyboard 18 is a part of the basic input and output system (BIOS).

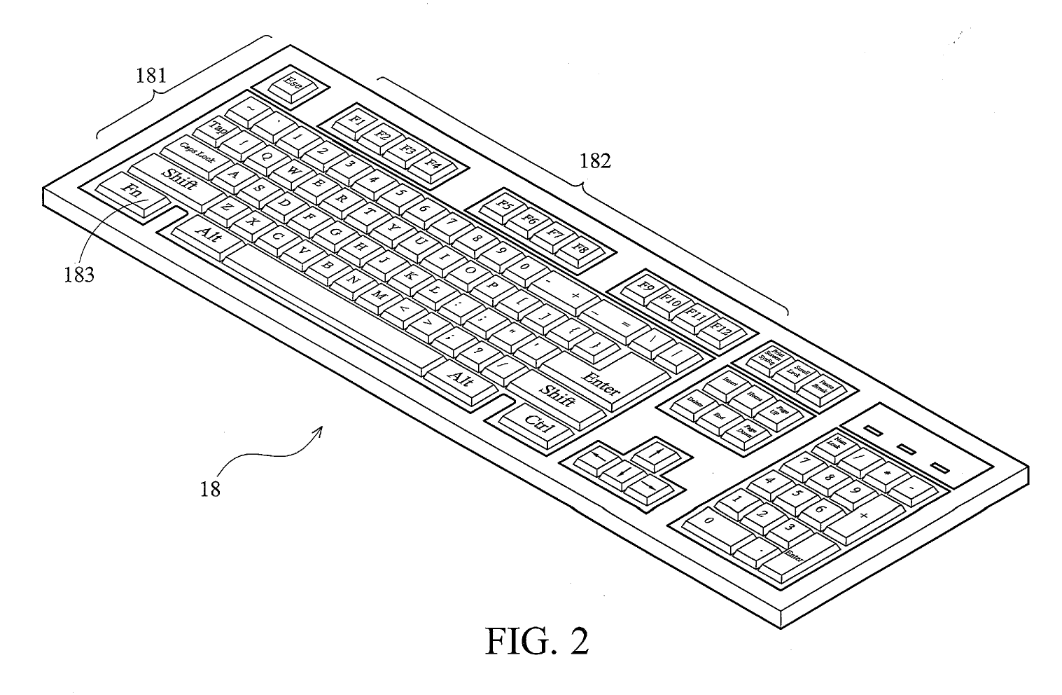

FIG. 2 is a schematic diagram showing the keyboard 18. The keyboard 18 includes several conventional alphanumeric keys 181, several function keys 182, and an Fn key 183. For example, the alphanumeric keys 181 includes the English letter keys a˜z, the number keys 0˜9, the Ctrl key, the Shift key, the Alt key and so on. The function keys 182 includes at least F1˜F12. The keyboard controller 22 is coupled to the keyboard 18 to detect whether the alphanumeric keys 181, the function keys 182 and the Fn key 183 are pressed.

In the embodiment, when the Fn 183 and any one of the function keys (F1˜F12) 182 or the Fn key 183 and any one of the alphanumeric keys 181 are pressed, the keyboard controller 22 generates a predetermined scan code. In this embodiment, the scan code is E023. At this moment, the keyboard controller 22 also generates a corresponding event code and stores the corresponding event code in the event code buffer 223.

Table 1 is a comparison table of the event codes and the corresponding service programs of the embodiment of the invention.

TABLE 1

| event code | the pressed keys | the corresponding function |
|---|---|---|
| ECD01 | Fn + F2 | executing the network access program |
| ECD02 | Fn + F3 | opening the keyboard locking |
| ECD03 | Fn + F4 | outputting images to a projector |
| ECD04 | Fn + F5 | executing the pausing function of the |
| | | audio and video program |
| ECD05 | Fn + F6 | executing the fast forwarding function |
| | | of the audio and video program |
| ECD06 | Fn + F7 | executing the reversing function of the |
| | | audio and video program |
| ECD07 | Fn + F8 | executing the sleeping mode |
| ECD08 | Fn + F9 | increasing the brightness of the screen |
| ECD09 | Fn + F10 | decreasing the brightness of the screen |
| ECD10 | Fn + F11 | turning up the volume of the |
| | | loudspeaker |
| ECD11 | Fn + F12 | turning down the volume of the |
| | | loudspeaker |
| ECD12 | Fn + Backspace | executing the mute function |

For example, when the Fn key 183 and the F2 key of the function keys 182 are pressed, the keyboard controller 22 generates the predetermined scan code E023 and an event code ECD01, which represents that the user wants to execute an network access program. If the Fn key 183 and the F3 key of the function keys 182 are pressed, the keyboard controller 22 generates the predetermined scan code E023 and a corresponding event code ECD02, which represents that the user wants to open the keyboard locking to lock the keyboard 18. When the Fn key 183 and the F8 key of the function keys 182 are pressed, the keyboard controller 22 generates the predetermined scan code E023 and a corresponding event code ECD07, which represents the user wants to execute the sleeping mode to save the electric power. In other embodiment, when the Fn key 183 and any of the number keys 181 are pressed, the keyboard controller 22 also can generate the predetermined scan code E023 and a corresponding event code.

When the alphanumeric number 181, the function keys 182, the key combination thereof or hotkeys are pressed, the keyboard controller 22 generates corresponding scan codes which do not include the predetermined scan codes E023, which represents that the Fn key 183 is not pressed.

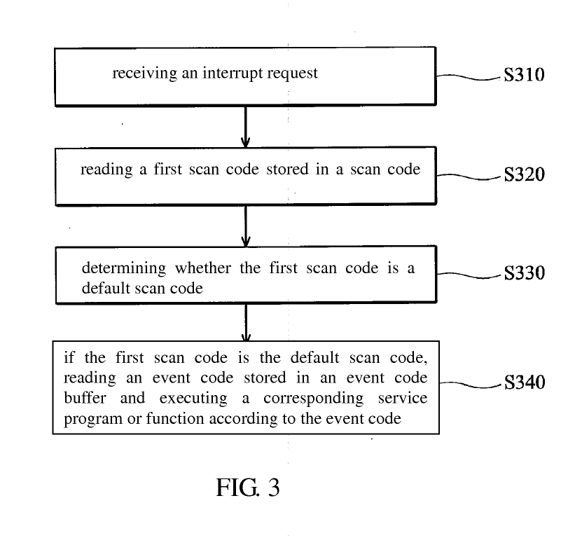

FIG. 3 is a flowchart of the method for processing keyboard input of one embodiment of the invention. The flowchart is executed by the processing unit 10. The steps are receiving an interrupt request at the step S310, reading the scan code stored in the scan code buffer at the step S320, determining whether the scan code represents the predetermined scan code of the Fn key at the step S330, and if the scan code is the predetermined scan code, reading an event code stored in an event code buffer and executing a corresponding service program or function according to the event code.

The method of the embodiment of the invention is described hereinbelow. The method is executed by the processing unit 10. Please refer to FIG. 1 and FIG. 2.

When the processing unit 10 detects the keyboard interrupt request sent by the interrupt controller 24, it executes a corresponding KBSR. Generally speaking, the interrupt controller 24 can generate different interrupt requests to inform the processing unit 10 according to the interrupt signals such as IRQ0˜IRQ15 sent by different modules, and the processing unit 10 executes the corresponding interrupt service routine. In the embodiment, when any key or any combination key on the keyboard 18 are pressed, the interrupt controller 24 sends the keyboard interrupt request to inform the processing unit 10 according to the interrupt signal IRQ1 generated by the keyboard controller 22, so that the processing unit 10 can execute the KBSR.

The keyboard interrupt request is generated when the interrupt controller 24 detects the interrupt signal IRQ1 sent by the keyboard controller 22, and the interrupt signal IRQ1 is generated when the keyboard controller 22 detects that the Fn key 183, the alphanumeric keys 181, the function keys (F1˜F12) 182, the combination of Fn key 182 and the alphanumeric keys 181 or the combination of the Fn key 183 and the function keys 182 is pressed.

The scan code stored in the scan code buffer 221 in the keyboard controller 22 may be read via the KBSR first, and a filter program (FP) may be called to determine whether the scan code is the predetermined scan code in this embodiment. In this embodiment, the FP is stored in the disk drive or BIOS of the computer 100. In the preferred embodiment of the invention, the predetermined scan code represents the scan code which is generated when the key combination of the Fn key 183 and defined keys on the keyboard 18 is pressed by the user. For example, the predetermined scan code is E023, but there is no limitation thereon.

When the FP determines that the current scan code is the predetermined scan code (E023), the FP reads the event code stored in the event code buffer 223 in the keyboard controller 22, so that the BIOS or the application program in the computer 100 can execute a corresponding service program (or function) according to the obtained event code.

For example, as shown in table 1, if the read event code is ECD01 which represents that the Fn key 183 and the function key F2 are pressed by the user, the computer 100 executes a service program to execute the network access program.

In other words, the BIOS in the computer 100 can selectively execute a corresponding service program according to the read event code to execute functions such as opening the keyboard locking, executing the network access program, outputting images to a projector, executing the pausing function of the audio and video program, executing the fast forwarding function of the audio and video program, executing the reversing function of the audio and video program, executing the sleeping mode, increasing the brightness of the screen, decreasing the brightness of the screen, turning up the volume of the loudspeaker, turning down the volume of the loudspeaker, executing the mute function, and so on.

If the FP determines that the read scan code is not the predetermined scan code (E023), the KBSR executes the function corresponding to the press, which is, for example, converting the scan code obtained by the KBSR to the ASCII character representing the alphanumeric key pressed by the user or executing the function determined by the pressed character.

No matter the KBSR or the FP executes the relative operation, the relative operation still need do relative calculation via the processing unit 10. Therefore, in the description of the preferred embodiment of the invention, the processing unit 10 determines whether the scan code in the keyboard controller 22 is the predetermined code of the Fn key, and if the scan code in the keyboard controller 22 is the predetermined scan code, the processing unit 10 reads the event code stored in the event code buffer, and the processing unit 10 can execute a corresponding service program or function according to the event code.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A method for processing keyboard input, the method comprising the steps of:
receiving an interrupt request;
reading a first scan code stored in a scan code buffer;
determining whether the first scan code is a predetermined scan code; and
reading an event code stored in an event code buffer and executing a corresponding service program or function according to the event code if the first scan code is the predetermined scan code.

2. The method according to claim 1, wherein the first scan code is generated when an Fn key or the combination of the Fn key and an other key on the keyboard is pressed.

3. The method according to claim 1, wherein the interrupt request is generated when a south bridge chip detects an interrupt signal.

4. The method according to claim 1, wherein the interrupt signal is generated when an Fn key, a function key, an alphanumeric key or two of them are pressed.

5. The method according to claim 1, wherein when the combination of an Fn key and a function key or the combination of an Fn key and an alphanumeric key is pressed, the first scan code is stored to the scan code buffer and the event code is stored to the event code buffer.

6. A computer comprising:
a keyboard comprising a plurality of alphanumeric keys, a plurality of function keys and an Fn key;
a processing unit; and
a keyboard controller coupled to the keyboard so that the keyboard controller generates an interrupt signal to make the processing unit execute a corresponding service program or function when one of the alphanumeric keys, one of the function keys, the Fn key or the key combination thereof is pressed.

7. The computer according to claim 6, wherein the computer further comprises a south bridge chip coupled between the processing unit and the keyboard controller, the south bridge chip generating an interrupt request to make the processing unit execute the corresponding service program or function when the south bridge chip receives the interrupt signal from the keyboard controller.

8. The computer according to claim 7, wherein, the processing unit reads a first scan code stored in a scan code buffer and determines whether the first scan code is a predetermined scan code representing the Fn key which is pressed after the processing unit receives the interrupt request, if the first scan code is the predetermined scan code, the processing unit reads an event code stored in an event code buffer and executes a corresponding service program or function according to the event code.

9. A computer comprising:
a keyboard comprising a plurality of alphanumeric keys, a plurality of function keys and an Fn key;
a keyboard controller coupled to the keyboard and comprising a scan code buffer and an event code buffer; and
a processing unit, reading a first scan code stored in the scan code buffer and determining whether the first scan code is a predetermined scan code representing the Fn key after receiving an interrupt request, if the first scan code is the predetermined scan code, the processing unit reads an event code stored in an event code buffer and executes a corresponding service program or function according to the event code.

10. The computer according to claim 9, wherein the keyboard controller generates the first scan code and stores the first scan code to the scan code buffer when the Fn key is pressed.

11. The computer according to claim 10, wherein the keyboard controller generates the interrupt signal when the keyboard controller detects that the Fn key, one of the function keys, one of the alphanumeric keys or two of them are pressed, the keyboard controller generates the interrupt signal.

12. The computer according to claim 11, wherein the keyboard controller stores the first scan code to the scan code buffer and stores the event code to the event code buffer when the combination of the Fn key and one of the function keys or the combination of the Fn key and one of the alphanumeric keys is pressed.

13. The computer according to claim 9, wherein the computer further comprises an interrupt controller for generating the interrupt request according to the interrupt signal.

14. The computer according to claim 13, wherein the interrupt controller is provided in a south bridge chip.
